(19) United States
(12) Patent Application Publication
(10) Pub. No.: US 2022/0418127 A1
(43) Pub. Date: Dec. 29, 2022

(54) Waterproof remote key device with floats

(71) Applicants: Yui Chen Liu, Shenzhen (CN); Yu-Chen Liu, Shenzhen (CN)

(72) Inventors: Yui Chen Liu, Shenzhen (CN); Yu-Chen Liu, Shenzhen (CN)

(21) Appl. No.: 17/823,522

(22) Filed: Aug. 31, 2022

(51) Int. Cl. H05K 5/02; H04B 1/034; H05K 7/14

(52) U.S. Cl. CPC H05K 5/0217; H04B 1/034; H05K 7/1427; H04B 2001/3894

(57) ABSTRACT

A remote key device includes a housing including a first waterproof compartment and two second waterproof compartments spaced from front and rear ends of the first waterproof compartment respectively; two floats disposed in the second waterproof compartments respectively; and a PCB disposed in the first waterproof compartment. There are further provided with a first space disposed between the first waterproof compartment and one of the second waterproof compartments, and a second space disposed between the first waterproof compartment and the other second waterproof compartment. There are further provided with a frame disposed on the first waterproof compartment and a sealing member disposed on the frame.

### FIELD OF THE INVENTION

The invention relates to remote key devices and more particularly to a waterproof remote key device having two floats.

### BACKGROUND OF THE INVENTION

A remote key device can be operated remotely to open (or close) a door rather than inserting a key into a keyhole to open (or close) the door.

A conventional remote key device with a waterproof arrangement is commercially available. However, it cannot float. Thus, it may sink after dropping into the water.

Thus, the need for improvement still exists.

### SUMMARY OF THE INVENTION

The invention has been made in an effort to solve the problems of the conventional art including incapable of floating by providing a remote key device having novel and nonobvious characteristics.

To achieve above and other objects of the invention, the invention provides a remote key device comprising a housing including a first waterproof compartment and two second waterproof compartments spaced from front and rear ends of the first waterproof compartment respectively; two floats disposed in the second waterproof compartments respectively; and a printed circuit board (PCB) disposed in the first waterproof compartment.

Preferably, the embodiment the PCB is fastened in the first waterproof compartment by means of fasteners.

Preferably, there are further provided with a first space disposed between the first waterproof compartment and one of the second waterproof compartments, and a second space disposed between the first waterproof compartment and the other second waterproof compartment.

Preferably, there are further provided with a frame disposed on the first waterproof compartment and a sealing member disposed on the frame.

Preferably, the floats have different sizes.

Preferably, the housing further comprises an upper shell and a lower shell releasably secured together.

Preferably, the first waterproof compartment, the second waterproof compartments, and the spaces are provided in the lower shell.

Preferably, there are further provided two first latches provided on bottoms of front and rear ends of the upper shell respectively and two first complementary members provided in the second waterproof compartments respectively, the first latches being fastened by the first complementary members respectively when the upper shell is closed onto the lower shell.

Preferably, there are further provided a plurality of second latches provided on either side of the upper shell and a plurality of second complementary members provided on either side of the lower shell, the second latches being fastened by the second complementary members respectively when the upper shell is closed onto the lower shell.

Preferably, the floats are spherical or multisided.

Preferably, the upper shell and the lower shell are secured together by means of ultrasonic welding.

The remote key device of the invention has the following advantageous effects in comparison with the prior art: the remote key device can float due to the provisions of the housing, the first waterproof compartment, the second waterproof compartments, and the floats (or the airtight compartments) if it accidentally drops into the water. This arrangement can decrease monetary loss of the user. Its manufacturing process is simple, quick and efficient. The ultrasonic welding is optional since it does not adversely affect floating capability of remote key device. It is cost effective and has wide applications.

The above and other objects, features and advantages of the invention will become apparent from the following detailed description taken with the accompanying drawings.

### BRIEF DESCRIPTION OF THE DRAWINGS

FIG. 1 is an exploded view of a remote key device according to a first embodiment of the invention;

FIG. 2 is a longitudinal sectional view of the assembled remote key device of FIG. 1;

FIG. 3 is an exploded view of a remote key device according to a second embodiment of the invention; and

FIG. 4 is a longitudinal sectional view of the assembled remote key device of FIG. 3.

### DETAILED DESCRIPTION OF THE INVENTION

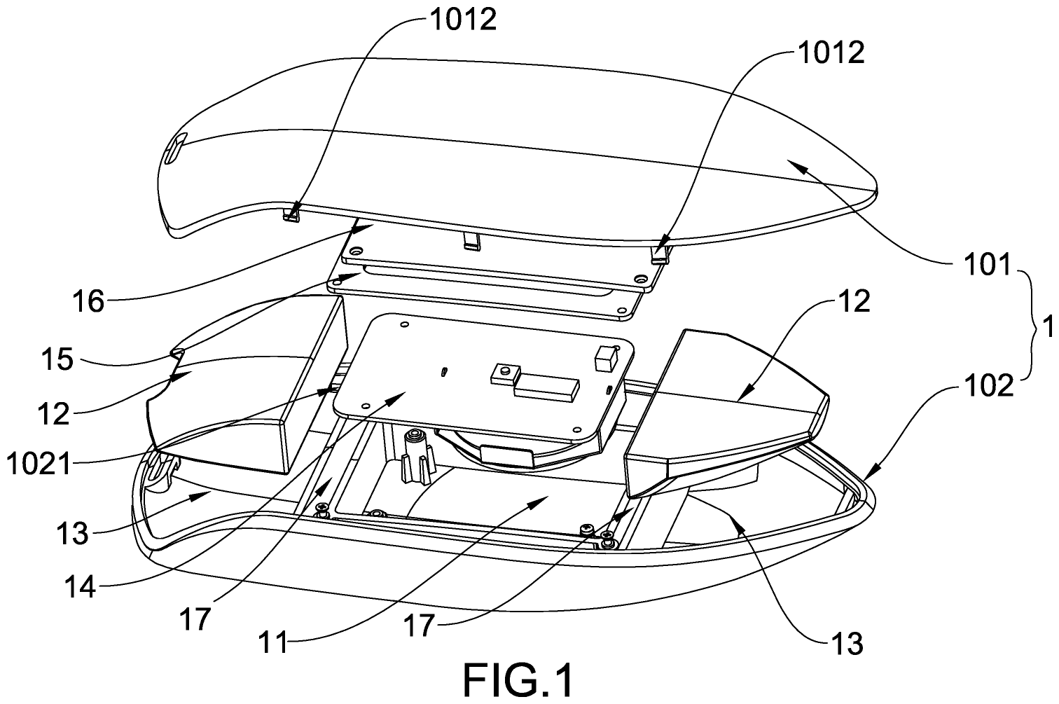

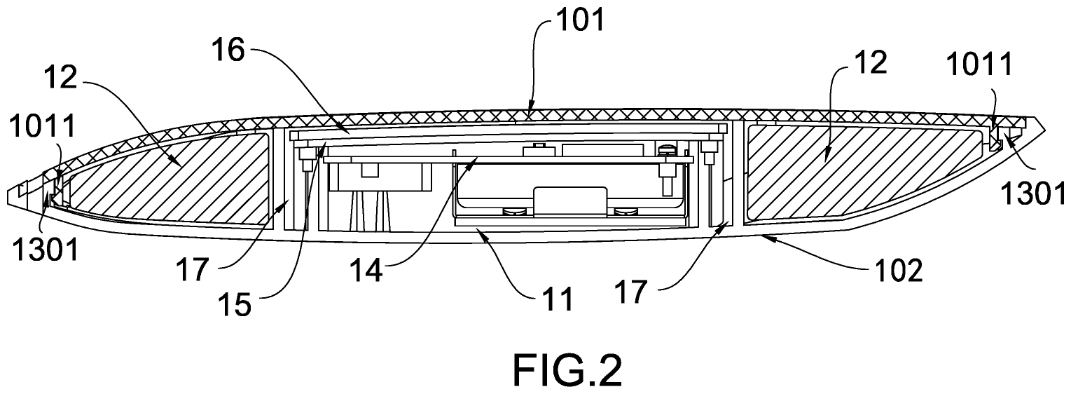

Referring to FIGS. 1 to 2, a remote key device in accordance with a first embodiment of the invention comprises a housing 1, two floats 12, and a printed circuit board (PCB) 14 as discussed in detail below. The housing 1 includes an upper shell 101 and a lower shell 102 secured to the upper shell 101. The housing 1 further comprises a first waterproof compartment 11 with the PCB 14 disposed therein, and two second waterproof compartments 13 spaced from front and rear ends of the first waterproof compartment 11 respectively. The floats 12 are disposed in the second waterproof compartments 13 respectively.

The PCB 14 is fastened in the first waterproof compartment 11 by means of fasteners. Thus, water is prevented from going through the first waterproof compartment 11 to damage the PCB 14.

Two spaces 17 are provided in which one is disposed between the first waterproof compartment 11 and one second waterproof compartment 13 and the other is disposed between the first waterproof compartment 11 and the other second waterproof compartment 13. The provision of the space 17 separates the first waterproof compartment 11 from either second waterproof compartment 13.

A frame 15 is disposed on the first waterproof compartment 11 and a sealing member 16 is disposed on the frame 15. Both the frame 15 an the sealing member 16 are covered by the upper shell 101.

This further prevents water from going into the first waterproof compartment 11 to damage the PCB 14.

The floats 12 have different sizes so as to fully utilize the limited internal space of the remote key device. As a result, the float functionality of the remote key device can be maintained.

The first waterproof compartment 11, the second waterproof compartments 13 and the spaces 17 are provided in the lower shell 102. Two first latches 1011 are provided on bottoms of front and rear ends of the upper shell 101 respectively and two first complementary members 1301 are provided in the second waterproof compartments 13 respectively. A plurality of second latches 1012 are provided on either side of the upper shell 101 and a plurality of second complementary members 1021 are provided on either side of the lower shell 102. The first latches 1011 are fastened by the first complementary members 1301 respectively and the second latches 1012 are fastened by the second complementary members 1021 respectively when the upper shell 101 is closed onto the lower shell 102.

Preferably, the floats 12 are spherical or multisided.

Preferably, shapes of the floats 12 are accommodated to the internal space of the housing 1. The floats 12 can be disposed in any places of the housing 1 other than the first waterproof compartment 11 and the spaces 17. Further, the number of the floats 2 can be one and the single float is bigger than the floats 2 shown in FIGS. 1 and 2. Alternatively, the number of the floats 2 is more than two as long as the desired floating effect can be achieved.

Preferably, the upper shell 101 and the lower shell 102 are secured together by means of ultrasonic welding. Alternatively, the upper shell 101 and the lower shell 102 are secured together by means of method other than ultrasonic welding. Both are possible because the remote key device can be floated by the floats 12.

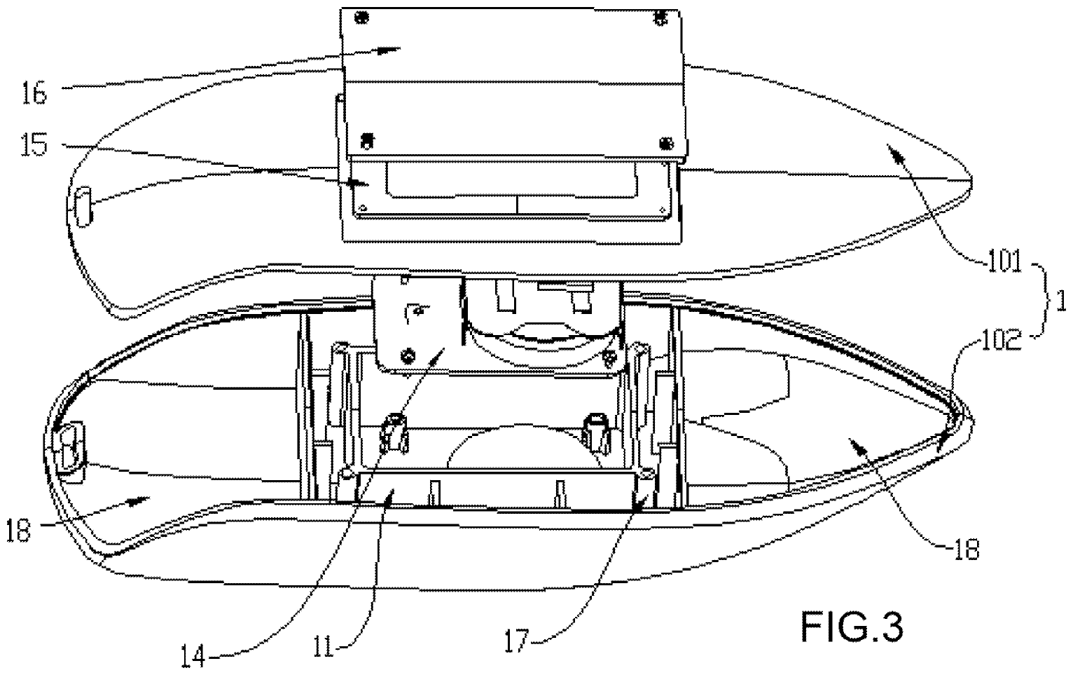

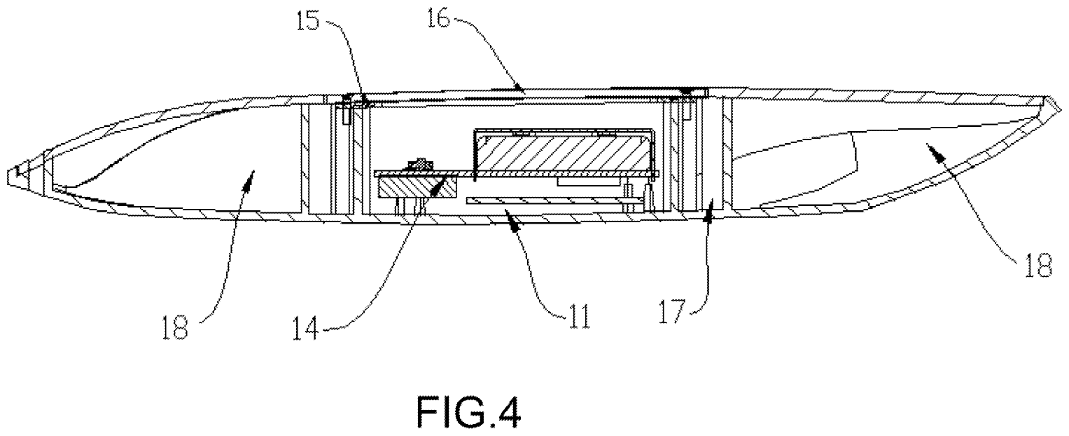

Referring to FIGS. 3 to 4, a remote key device in accordance with a second embodiment of the invention is shown. The characteristics of the second preferred embodiment are substantially the same as that of the first preferred embodiment except the following: the upper shell 101 and the lower shell 102 are secured together by means of ultrasonic welding or adhesive. Thus, a snapping mechanism for securing the upper shell 101 to the lower shell 102 is not required. The second waterproof compartments 13 are replaced by two airtight compartments 18. The floats are not required due to buoyancy of the airtight compartments 18. The sealing member 16 is disposed on the frame 15 which is disposed on the upper shell 101. A person may open the sealing member 16 to repair any malfunctioned components of the remote key device.

In the first embodiment, the upper shell 101 and the lower shell 102 are secured together. To the contrary, in the second embodiment, the upper shell 101 and the lower shell 102 are formed as a whole and the sealing member 16 is provided on a central portion of a top of the housing. The housing can be implemented in any embodiments other than above. Also, buoyancy of the remote key device can be implemented in any other devices other than the floats 12 of the first embodiment and the airtight compartments 18 of the second embodiment.

It is envisaged by the invention that the remote key device can float due to provisions of the housing 1, the first waterproof compartment 11, the second waterproof compartments 13, and the floats 12 (or the airtight compartments 18) if it accidentally drops into the water. This arrangement can decrease monetary loss of the user. Its manufacturing process is simple, quick and efficient. The ultrasonic welding is optional since it does not adversely affect floating capability of remote key device. It is cost effective and has wide applications.

While the invention has been described in terms of preferred embodiments, those skilled in the art will recognize that the invention can be practiced with modifications within the spirit and scope of the appended claims.

What is claimed is:

1. A remote key device, comprising:
a housing including a first waterproof compartment and two second waterproof compartments spaced from front and rear ends of the first waterproof compartment respectively;
two floats disposed in the second waterproof compartments respectively; and
a printed circuit board (PCB) disposed in the first waterproof compartment.

2. The remote key device of claim 1, wherein the PCB is fastened in the first waterproof compartment by means of fasteners.

3. The remote key device of claim 2, further comprising a first space disposed between the first waterproof compartment and one of the second waterproof compartments, and a second space disposed between the first waterproof compartment and the other second waterproof compartment.

4. The remote key device of claim 3, further comprising a frame disposed on the first waterproof compartment and a sealing member disposed on the frame.

5. The remote key device of claim 1, wherein the floats have different sizes, and the housing further comprises an upper shell and a lower shell releasably secured together.

6. The remote key device of claim 5, wherein the first waterproof compartment, the second waterproof compartments, and the spaces are provided in the lower shell.

7. The remote key device of claim 6, further comprising two first latches provided on bottoms of front and rear ends of the upper shell respectively and two first complementary members provided in the second waterproof compartments respectively, the first latches being fastened by the first complementary members respectively when the upper shell is closed onto the lower shell.

8. The remote key device of claim 7, further comprising a plurality of second latches provided on either side of the upper shell and a plurality of second complementary members provided on either side of the lower shell, the second latches being fastened by the second complementary members respectively when the upper shell is closed onto the lower shell.

9. The remote key device of claim 4, wherein the floats are spherical or multisided.

10. The remote key device of claim 8, wherein the upper shell and the lower shell are secured together by means of ultrasonic welding.
